(19) United States
(12) Patent Application Publication
(10) Pub. No.: US 2017/0326689 A1
(43) Pub. Date: Nov. 16, 2017

(54) METHODS OF FORMING A SUBSTRATE HAVING AN OPEN PORE THEREIN AND PRODUCTS FORMED THEREBY

(71) Applicant: Purdue Research Foundation, West Lafayette, IN (US)

(72) Inventors: Alexander Wei, West Lafayette, IN (US); Naveen Reddy Kadasala, West Lafayette, IN (US); Gary J. Cheng, West Lafayette, IN (US); Mojib Saei, Lafayette, IN (US)

(21) Appl. No.: 15/593,906

(22) Filed: May 12, 2017

Related U.S. Application Data
(60) Provisional application No. 62/336,553, filed on May 13, 2016.

(51) Int. Cl. B23K 26/386; H05K 3/04; H01L 21/677; H01L 21/027; H01L 21/02; H05K 3/42

(52) U.S. Cl. CPC B23K 26/386; H05K 3/42; H05K 3/04; H01L 21/0203; H01L 21/0275; H01L 21/02422; H01L 21/67709

(57) ABSTRACT

Methods and products formed thereby that include depositing a light-absorbing particle on a substrate and irradiating the particle with a pulsed laser beam to cause an increase in local temperature of a portion of the substrate contacted by and adjacent to the particle, enabling the particle to penetrate and migrate through the substrate to form a pore. The methods may include additional steps of applying a magnetic field gradient to the particle as the particle is irradiated with the laser beam in order to promote the movement of the particle within the substrate or to direct the movement of the particle within the substrate, and/or the step of filling the pore with a material that provides a functional capability independent of the properties of the substrate.

### CROSS REFERENCE TO RELATED APPLICATIONS

This application claims the benefit of U.S. Provisional Application No. 62/336,553, filed May 13, 2016, the contents of which are incorporated herein by reference.

### BACKGROUND OF THE INVENTION

The present invention generally relates to the production of open pores in a variety of substrates. The invention particularly relates to the formation of high-aspect ratio wells (blind pores) and/or channels (through-pores) in surfaces of substrates using particles irradiated by a pulsed laser beam to cause the particles to penetrate the substrate, optionally aided by magnetic field gradients. These substrates containing open porosity can be infiltrated with materials for added functionality.

Nanoporous materials can be classified in part according to their pore size. According to IUPAC, microporous materials have pore diameters of 0.2-2 nm, mesoporous materials have pore diameters between 2 and 50 nm, and macroporous materials have pore diameters of 50-1000 nm. Nanoporous materials, particularly macroporous thin films, are widely used in technologies for chemical purification, size-dependent removal of contaminants, as separators in microstructured fuel cells and lithium-ion batteries, and as templates for the growth of nanowires or high-aspect ratio electrodes. One method to produce nanoporous substrates is by ion-track etching in polymer thin films by bombardment with heavy-element ions (Z>50) followed by controlled etching under alkali conditions. Other methods of producing nanoporous substrates include the anodization of aluminum substrates, self-organization of pores from cast polymer solutions under dissipative conditions, selective etching of self-assembled block copolymer films, and etching of defects introduced by nanoimprint lithography.

These conventional methods have several shortcomings. For example, ion-track etching processes generally require a high-energy ionization source such as a particle accelerator operating under carefully controlled temperatures to prevent substrate warping. In addition, there is a subsequent wet-etching process that must be performed offline, and can take several hours before the desired pore size is achieved. This limits the scalability of nanoporous membrane production with well-defined channels.

In view of these shortcomings, there is a need for methods to produce nanoporous materials, preferably under ambient conditions and temperatures without a wet chemical etching process.

### BRIEF DESCRIPTION OF THE INVENTION

The present invention provides methods suitable for producing nanoporous substrates comprising open, high-aspect ratio channels, and products formed thereby.

According to one aspect of the invention, a method is provided that includes depositing a particle on a substrate and irradiating the particle with a pulsed laser beam to cause an increase in local temperature of a portion of the substrate contacted by and adjacent to the particle, enabling the particle to penetrate and migrate through the substrate to form a pore.

According to another aspect of the invention, a product is provided that is produced by a method comprising the steps described above.

Other aspects of the invention include a method as described above wherein the method includes applying a magnetic field gradient to a magnetic particle as the particle is irradiated with the pulsed laser beam in order to promote the movement of the particle within the substrate or to direct the movement of the particle within the substrate, and/or includes filling the pore with a material that provides a functional capability independent of the properties of the substrate.

Technical effects of the methods described above preferably include the ability to produce nanoporous substrates without the necessity of a wet chemical etching process. Such methods may optionally be implemented as high-yield continuous processes performed at ambient temperatures.

Other aspects and advantages of this invention will be further appreciated from the following detailed description.

### BRIEF DESCRIPTION OF THE DRAWINGS

FIG. 1 schematically represents a nonlimiting process for producing open pores in a substrate in accordance with certain aspects of the present invention.

FIG. 2 includes scanning electron microscopy (SEM) images demonstrating pores formed with magnetic gold nanoclusters (MGNCs) in borosilicate glass having a thickness of 4 mil (100 μm). Image “a” shows a channel produced by single MGNC with a width of about 110 nm. Image “b” shows that as the MGNCs approach the bottom of the substrate, the applied magnetic field gradient is no longer in axial alignment with laser irradiation causing a substantial deviation in their trajectories.

FIG. 3 shows a nonlimiting system for producing open pores in a substrate over a magnetic stage using a scanning pulsed laser in accordance with certain aspects of the present invention.

FIG. 4 includes an illustration of a MGNC and a transmission electron microscopy (TEM) image of MGNCs (scale bar=50 nm).

FIG. 5 is a SEM image that shows nanoparticles deposited on a surface of a polyethylene terephthalate (PET) substrate.

FIG. 6 includes four images showing nanopores produced in 3-mil (75 μm) PVDF film using the system of FIG. 3. Operation of the system for ten cycles at seven percent power was sufficient to initiate nanopore formation, and thirty cycles was sufficient to generate full channels. Images “a” and “b” show the top and bottom, respectively, of nanopores formed with ten cycles and images “c” and d″ show the top and bottom, respectively, of nanopores formed with thirty cycles.

FIG. 7 includes four SEM images of open pores formed in a substrate in accordance with a process of the type represented in FIG. 1. Image “a” shows pores formed with magnetic gold nanoclusters (MGNCs) on a PET film at room temperature using a pulse energy of 85 mJ (1.2 MW/cm²) and uniaxial magnetic field gradient of 4.5 kG/cm. Image “b” shows pores formed in a PET film using a pulse energy of 65 mJ (2.1 MW/cm²) and the inset shows enlargement of a nanopore aperture. Images “c” and “d” show pores formed with MGNCs on a PET film cooled to −78° C., using pulse energies of 85 and 65 mJ, respectively. Inspection of the samples showed that the nanopores formed were of similar dimensions as those produced at room temperature.

FIG. 8 includes a 3D confocal fluorescence image (image “a”) demonstrating infiltration of a 1 mM rhodamine B solution in DMSO into high aspect-ratio through-pores (“channels”) created in a 2-mil (about 50 μm) PET film, generated by a process of the type represented in FIG. 1. The direction of channel exits are indicated by an arrow. Image “b” is a digitized rendering of 3D data showing a tapered geometry of isolated channels with shrinking pore diameters near the bottom of the substrate.

FIG. 9 is a 3D confocal fluorescence image demonstrating infiltration of a rhodamine B solution into high aspect-ratio blind pores (“wells”) created in a 2-mil (about 50 μm) PET film, generated by a process of the type represented in FIG. 1 but without a magnetic field gradient. The wells penetrate roughly half of the thickness of the film, demonstrating control over depth penetration in the process.

FIG. 10 includes two 3D confocal fluorescence images of a substrate penetrated with MGNCs and subsequently infiltrated with rhodamine B solution. Image “a” is a 3-mil (75 μm) polydivinylfluoride (PVDF) substrate, and image “b” is a 2-mil (50 μm) polytetrafluoroethylene (PFTE) substrate.

### DETAILED DESCRIPTION OF THE INVENTION

Disclosed herein are processes for producing spatially controlled porosity in substrates without the need for wet chemical etching. The processes involve irradiating light-absorbing particles, preferably nanoparticles, on at least one surface of a substrate with a pulsed laser beam (i.e., laser beam pulses or laser pulses) that causes particles to penetrate the surface and move at least partially through the substrate and thereby form open pores in the substrate surface. Specifically, pulsed laser irradiation increases the temperature of the particles, which serve as localized heat sources that can cause a transient phase transition in the substrate proximal to each of the particles. This phase transition is sufficient to allow the particles to penetrate and move through the substrate to form open pores, either completely through the substrate to form what are referred to herein as “through-pores” or “channels,” or arrested partially through the substrate to form what are referred to herein as “blind pores” or “wells.” Optionally, the movement of the particles may be promoted or directed (guided) with a magnetic field gradient.

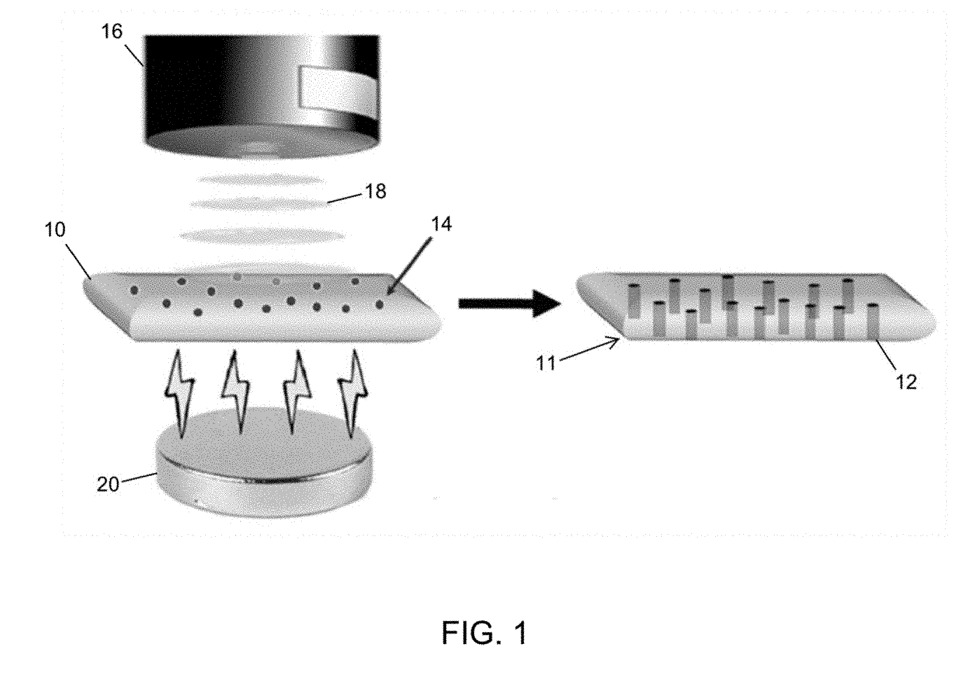

FIG. 1 schematically represents steps of a nonlimiting process and a nonlimiting apparatus for producing a product 11 comprising a substrate 10 having an array of pores 12, represented as channels. In this embodiment, nanoparticles 14 containing a magnetizable material are deposited onto a surface of the substrate 10. Various methods may be used to deposit uniform or patterned coatings of the nanoparticles 14 onto the substrate 10. These include, but are not limited to, spin coating, electrospray deposition, microgravure deposition, inkjet deposition, microcontact printing, capillary force lithography, xerography, inkjet printing, and related dry-coating processes. It is within the scope of the invention that the nanoparticles 14 may be deposited on the substrate 10 at variable surface densities (measured in nanoparticles per unit of surface area).

A laser source 16 located above the substrate 10 is used to selectively direct laser pulses 18 onto the substrate surface and the nanoparticles 14 thereon. Preferably, the laser source 16 is a pulsed laser system that can operate at nano-, pico-, and/or femtosecond frequencies with wavelengths between 300 and 1200 nm. FIG. 1 shows an optional magnetic field gradient as being simultaneously applied to the nanoparticles 14 through the substrate 10. In this embodiment, the magnetic field gradient produced by a magnetic field source 20 and the propagation of photons from the laser source 16 are axially aligned with the surface normal of the substrate 10, such that the nanoparticles 14 are heated by the laser pulses 18 and are simultaneously subjected to the magnetic field gradient and travel in a direction normal to the surface on which the nanoparticles 14 were originally deposited. Application of the laser pulses 18 and the magnetic field gradient to the nanoparticles 14 results in the substrate 10 and the nanoparticles 14 thereon being sufficiently heated for localized melting of the substrate 10, enabling the transfer of kinetic energy from the laser pulses 18 and magnetomotive force to drive the nanoparticles 14 through the substrate 10. As the nanoparticles 14 penetrate into the substrate 10, their individual paths create voids or pores within the substrate 10 that define entrance apertures at the surface of the substrate 10. The embodiment represented in FIG. 1 shows this process as continuing until the nanoparticles 14 perforate the substrate 10 and exit a surface thereof opposite the surface to which the nanoparticles 14 were originally deposited, yielding open porosity in the substrate 10 comprising through-pores (channels) 12 that pass entirely through the substrate 10. The process may be performed at any temperature below the glass-transition temperature or heat deflection temperature of the substrate 10, for example at ambient conditions and temperature (e.g., 17-27° C.).

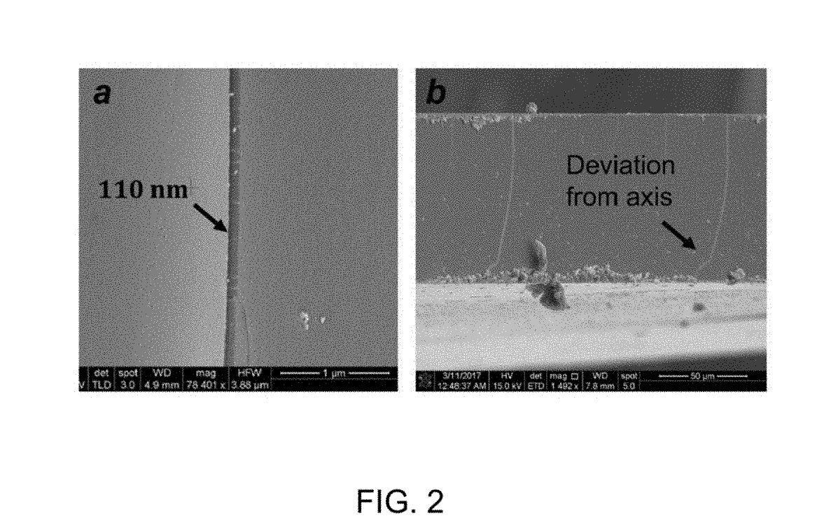

It is also within the scope of the invention that processes of the type described above may be performed to form either wells or channels in a substrate. Pore widths or diameters can be tuned as a function of particle size, laser pulse energy and power density, and also by the thermophysical properties of the substrate including coefficient of thermal expansion and heat deflection temperature. Processes of the type described above are capable of forming pores having a wide range of diameters, for example, average diameters between 0.05 and 5.0 μm, and more preferably between 50 and 100 nm. Although examples illustrated in the drawings and described herein represent the pores 12 as being formed along relatively linear paths and in a direction normal to the surface of the substrate 10 on which the nanoparticles 14 were deposited, it is within the scope of the invention that pores may be nonlinear and/or at various angles relative to surfaces of the substrate 10. For example, high aspect-ratio pores can be produced in a direction normal to a given surface of the substrate 10 by axially aligning the laser source 16 and magnetic field source 20 in a direction normal to the surface such that the nanoparticles 14 are driven through the substrate 10 along a common axis shared by the laser pulses 18 and the magnetic field gradient. Alternatively, the pores 12 may be produced at various angles by aligning the laser pulses 18 and magnetic field source 20 at an angle other than normal to the surface or by axially offsetting the laser pulses 18 and magnetic field source 20 relative to each other in a direction perpendicular to a normal to the surface. A nonlinear pore may be formed, for example, by using an offset alignment of the laser pulses 18 and the magnetic field gradient and/or varying the strength of the magnetic field gradient or moving the magnetic field source 20 relative to the laser pulses 18 as the nanoparticle 14 forming the nonlinear pore travels along a path through the substrate 10. Specifically, offsetting the alignment of the laser pulses 18 and the magnetic field gradient such that they are not aligned along a common axis may cause the nanoparticle 14 to move through the substrate 10 in a nonlinear path. For example, FIG. 2 shows a channel that was formed using a magnetic nanoparticle. Image “b” of FIG. 2 shows that the channel is curved near the bottom (lower surface) of the substrate. This structure was formed with a magnetic field gradient that was aligned with the laser pulses near the top (upper surface) of the substrate and not aligned near the bottom of the substrate. As shown, this variation in the alignment of the magnetic field gradient and the laser irradiation caused a substantial deviation in the trajectory of the nanoparticle. It is within the scope of the invention that processes of the type described above may be performed to variably form multiple pores in a substrate having various dimensions, linear and/or nonlinear paths, and/or various angles to produce a complex structure of open pores within the substrate. In view of the above, it is within the scope of the invention that the pores 12 may be generated along a predetermined path by controlling the forces (e.g., magnitude, duration, direction, etc.) acting on the nanoparticles 14 by the laser pulse 18 and the magnetic field gradient, for example, by adjusting the alignment, power levels, pulse rate, etc. of the laser source 16 and/or magnetic field source 20.

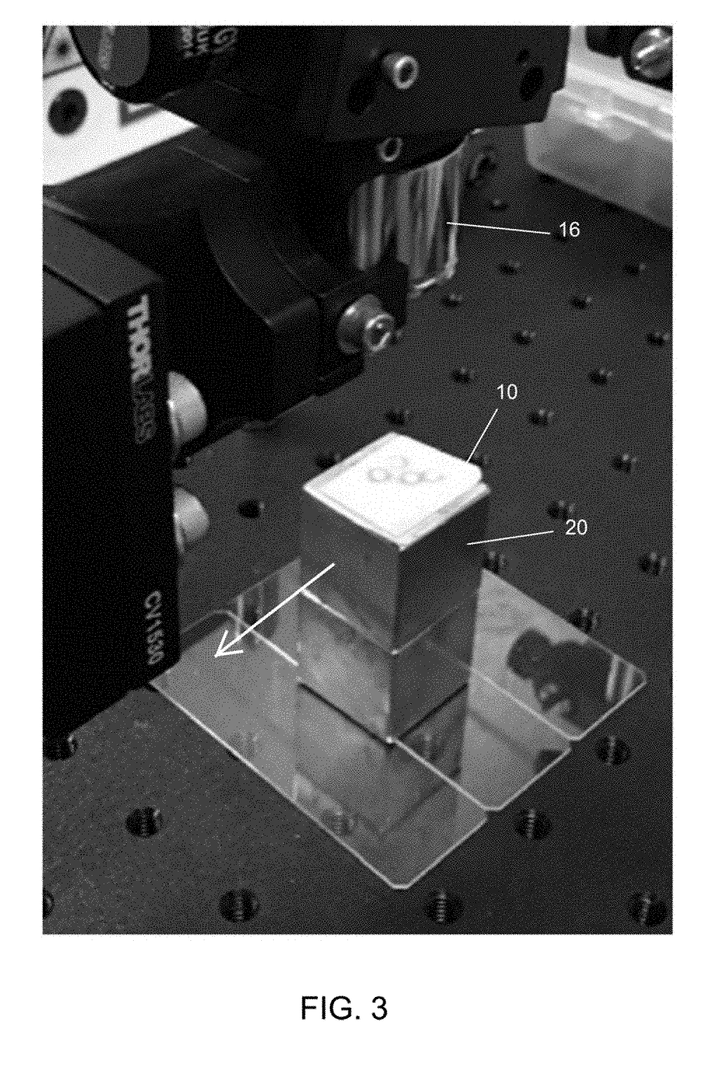

The process represented in FIG. 1 may be performed as a continuous manufacturing process. For example, the substrate 10 could be a web (e.g., roll substrate) of thin film continuously being moved in a travel direction. Downstream of a location where the nanoparticles 14 are deposited, a raster or patterned scan may be performed over the substrate 10 with the laser pulses 18. Such an embodiment could produce a high yield of thin film having the pores 12 therein, and is likely to provide higher throughput and lower overhead cost and energy consumption than conventional processes such as reactive ion-track etching. FIG. 3 shows a nonlimiting system for continuously producing open pores in a web over a magnetic stage using a scanning pulsed laser. The web may move in the direction indicated by the arrow while being scanned by the pulsed laser to continuously form the pores.

Such processes can be used to selectively form high aspect-ratio pores in a variety of two- and three-dimensional substrates. For example, the processes are applicable to various substrate materials including but not limited to thermoplastic and ceramic substrates. It should also be appreciated that the processes are applicable to substrates having various structures including but not limited to nonporous substrates, monolithic substrates, non-woven thin films, planar or faceted substrates, or nonplanar or curved substrates. Specific nonlimiting examples include thermoplastic web substrates, thermoplastic sheets, silicate (glass), alumina and aluminosilicate substrates, silicon nitride and silicon carbide, cermets, and various metal-oxides and dichalcogenides. Particularly suitable substrates are believed to have a thickness of between 1 and 10 mil (about 25 and 250 μm).

Nanoparticles suitable for use in the process described above may be formed of various materials, preferably a light-absorbing material with appreciable extinction in the near-ultraviolet to near-infrared wavelengths. Nonlimiting examples include metals, metal oxides and chalcogenides, carbides, carbon black, pnictides including nitrides, or combinations thereof. If the process includes the use of magnetic field gradients, the nanoparticles preferably comprise a magnetizable material, for example, a ferromagnetic metal such as iron, cobalt, nickel, etc. or their oxides, with a measurable magnetic moment that can enable response to the magnetic field gradients. In order to achieve both the desired light-absorbing and magnetic characteristics described above, the nanoparticles may be composites including more than one material. For example, the nanoparticles could include a core formed of a magnetizable material and an exterior coating thereon formed of light-absorbing material. Although the processes are described herein in reference to nanoparticles, it should be understood that the processes are not limited to using any particular size of particles. Nanoparticles are defined herein as particles having sizes (diameters or maximum dimension) of less than one micrometer, preferably having sizes of 100 nm or less.

In addition to the above, open pores created by processes as described herein can be impregnated with functional materials to perform a variety of functions. This enables one to develop nanoporous substrates for applications beyond separations and filtration. For example, the pores may be filled to generate customized “smart films” with additional capabilities such as, but not limited to, sensing or actuating functions that are independent of the substrate's properties. A nonlimiting example includes thin films with established barrier properties that are impregnated with sensors that can detect volatile analytes, for example, using changes in optical response for a device-free readout. Specific nonlimiting examples include thin films configured for monitoring volatile organic compounds related to food or beverage spoilage (e.g., ethylene, diamines, sulfides, and diacetyl), toxic or combustible gases in closed environments (e.g., CO, H₂, CH₄, SO₂, NO₂) or volatile compounds produced in exhaled breath that can be used as biomarkers for early detection of stress or disease (e.g., NO, aldehydes, ketones).

Other nonlimiting examples of functional materials for sensors in substrates include materials capable of changing their optical properties when complexed with a specific analyte, including volatile organics, fumigants (e.g., methyl bromide), herbicides, and pesticides, persistent organic pollutants (e.g., dioxins, polyhaloaromatics, PFOA), controlled substances (narcotics), high-energy compounds and accelerants used in explosives or incendiary devices (e.g., nitroaromatics, ketones, alcohol, ethers), heavy-metal ions, radioactive elements, and disease biomarkers. In such examples, microporous nanopowders and/or synthetic reporter molecules that are sensitive to local changes in their chemical microenvironment can be used to detect the adsorption of analytes based on simple optical signatures. In certain embodiments, the functional material may have a chromogenic response to an analyte (e.g., vapochromic and solvatochromic dyes). In another embodiment, the functional material may produce a change in photoemission in response to an analyte (fluorescence, luminescence, resonant light scattering).

Another potential application includes substrates comprising functional materials that contain microporous and mesoporous nanoparticles, including but not limited to zeolites, mesoporous silica and aluminosilicates, metal-organic and covalent-organic frameworks, and various species of gels. Similar to as discussed above in reference to the nanopores, the porous nanoparticles of said functional materials can be pre-loaded with sensor materials or catalysts to support chromatic transitions in response to analyte adsorption.

Another potential application includes thin-film circuits for flexible electronic devices. Such embodiments may include functional materials that support useful electronic or photonic properties. For example, a thin-film circuit could be formed to include through-pores (channels) filled with conductive or semiconductive materials, or a precursor that can be annealed into a conductive or semiconductive material.

Processes for filling the open pores include, but are not limited to, vacuum infiltration processes driven by a pressure gradient across the substrate, and application of liquid dispersions or slurries that exploit native or modified surface energies and wetting properties of the pores.

Nonlimiting embodiments of the invention will now be described in reference to experimental investigations leading up to the invention.

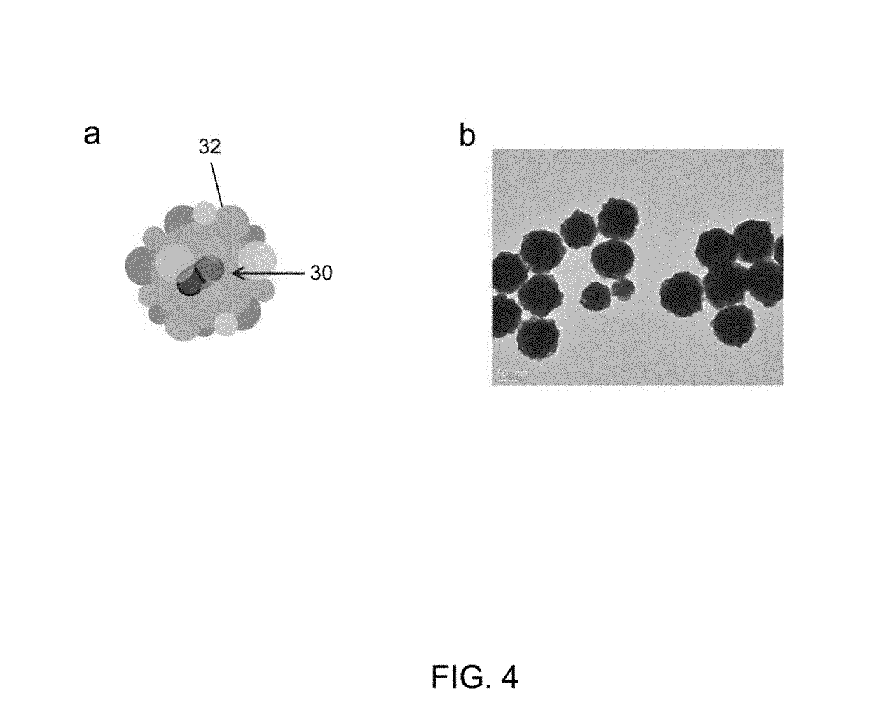

Thin films comprising an array of channels therein were produced with a process including the steps represented in FIG. 1 using the system of FIG. 3. In one investigation, magnetic gold nanoclusters (MGNCs) were prepared according to procedures disclosed in Kadasala et al., “Trace detection of tetrabromobisphenol A by SERS with DMAP-modified magnetic gold nanoclusters” (Nanoscale 2015, vol. 7, 10931) and Kadasala et al., “Eco-friendly (green) synthesis of magnetically active gold nanoclusters” (Sci. Technol. Adv. Mater. 2017, vol. 18, 210), the contents of which are incorporated herein in their entirety. Briefly, MGNCs were prepared from colloidal iron oxide (Fe₃O₄) produced by coprecipitation (2.5 to 3.0 wt. %), stabilized with polyethylene glycol, treated with histidine at pH 5, then mixed with HAuCl₄ and N-methylhydroxylamine (NMH) at pH 8-9 to produce the desired nanoparticles having an iron-oxide material 30 within a gold coating 32, as represented in image “a” of FIG. 4. Treatment with bis(hydroxyethyl-DTC) removed excess iron oxide without dissolving the MGNCs. Image “b” of FIG. 4 is a transmission electron microscopy (TEM) image showing cleansed MGNCs.

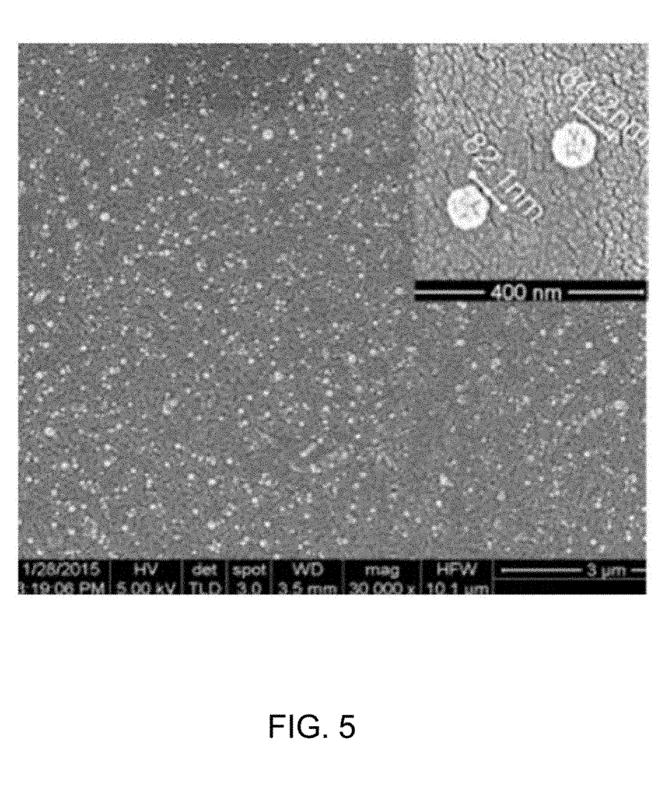

In certain investigations, aqueous suspensions of the MGNCs (dₐᵥ=100 nm) were produced having concentrations of 10 to 80 μg MGNCs per milliliter suspension. The suspensions were applied with a rod coater onto 2-mil polyethylene terephthalate (PET) substrates (ca. 50 μm thickness). Prior to deposition of the suspension, thin film substrates were treated with an oxygen plasma to promote desired wetting characteristics. The suspension-coated substrates were dried leaving a dispersed MGNC coating thereon, ranging from 3 to 20 particles/μm². FIG. 5 shows a PET substrate having nanoparticles deposited thereon.

In certain investigations, substrates were mounted over a NeFeB magnet with a measured field strength of 2.6 kG at the substrate surface, and a field gradient of 4.5 kG/cm. A stationary Q-switched Nd-YAG laser (wavelength 1064 nm, pulse duration 5 ns) operating at 5 Hz was focused into 2- or 3-mm spots on each of the substrates. About 50 to 200 laser pulses per spot (10 to 40 seconds laser irradiation time) were delivered for complete channel formation. The entire process is typically performed within a working range of about 3.2 to 5.4 mJ/pulse and power densities between 1.2 and 1.9 MW/mm².

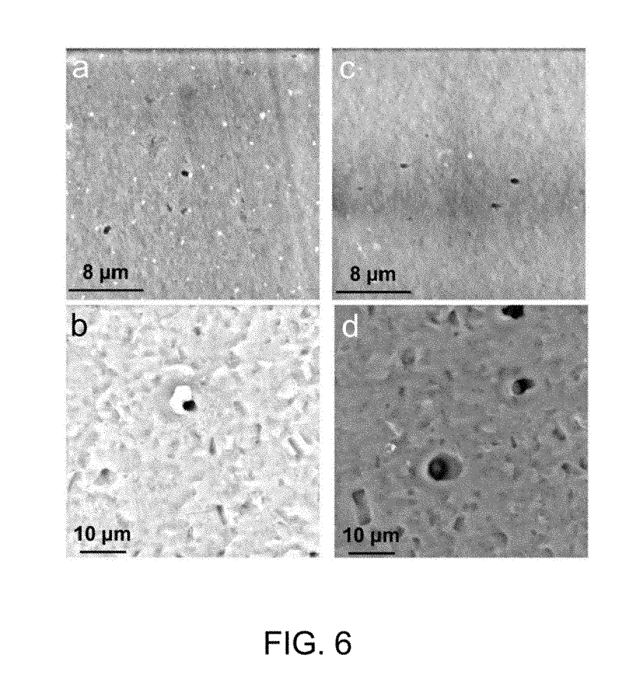

To establish the feasibility of using certain aspects of the invention as part of a continuous process, an investigation was conducted in which a process comprising the steps represented in FIG. 1 were performed with a scanning pulsed laser for various periods of time on 3-mil (75 μm) PVDF films having MGNCs deposited thereon. It was determined that no visible damage to the films was produced during pulsed laser scanning below a certain power threshold, although burning was possible if the laser beam was held stationary. FIG. 6 includes four images showing nanopores produced using the system of FIG. 3 with a laser power at a nominal setting of seven percent. Operation of the system for ten cycles was sufficient to initiate nanopore formation, and thirty cycles was sufficient to generate full channels. Images “a” and “b” show the top and bottom, respectively, of nanopores formed with ten cycles and images “c” and d″ show the top and bottom, respectively, of nanopores formed with thirty cycles.

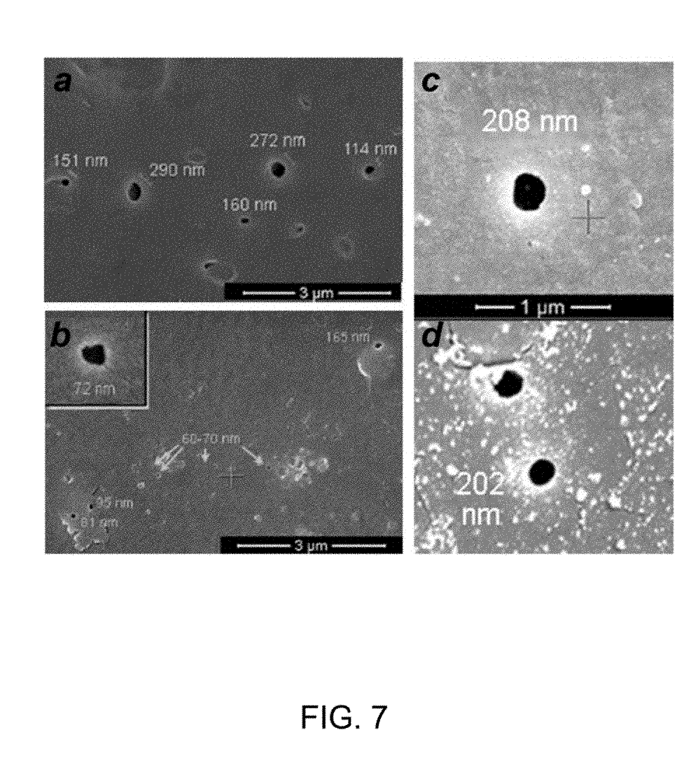

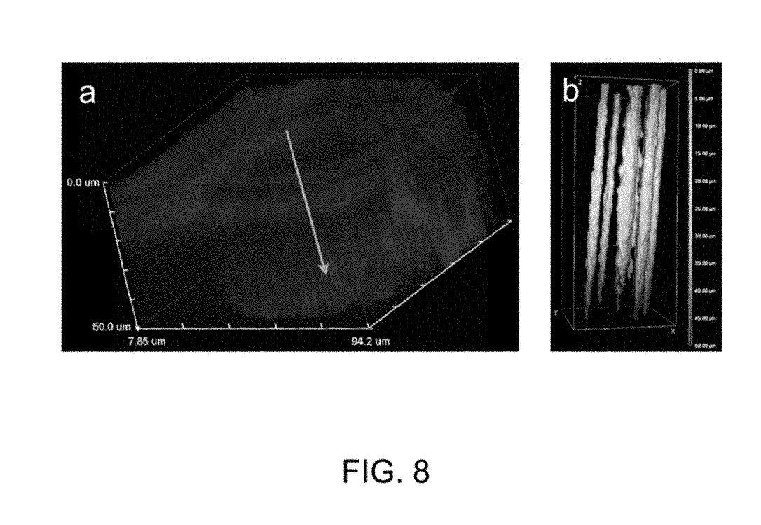

Referring to FIGS. 7 and 8, pore aperture diameters (pore widths at surfaces of the substrate) and pore channel diameters (pore widths within the substrate) were characterized by scanning electron microscopy (SEM) and 3D confocal fluorescence imaging, the latter supported by vacuum infiltration of 1 mM Rhodamine B (50% DMSO solution) into the channels. FIG. 7 includes four SEM images showing the pore aperture diameters in the PET substrates to be as small as about 60 nm. FIG. 8 includes a confocal fluorescence image (image “a”) that shows that the exit apertures of the pores are comparable in width to the nanoparticles, and also confirm nanosized channel formation (e.g., about 100 nm or less). The exit direction of the channels is indicated by a gray arrow pointed toward the bottom of the drawing.

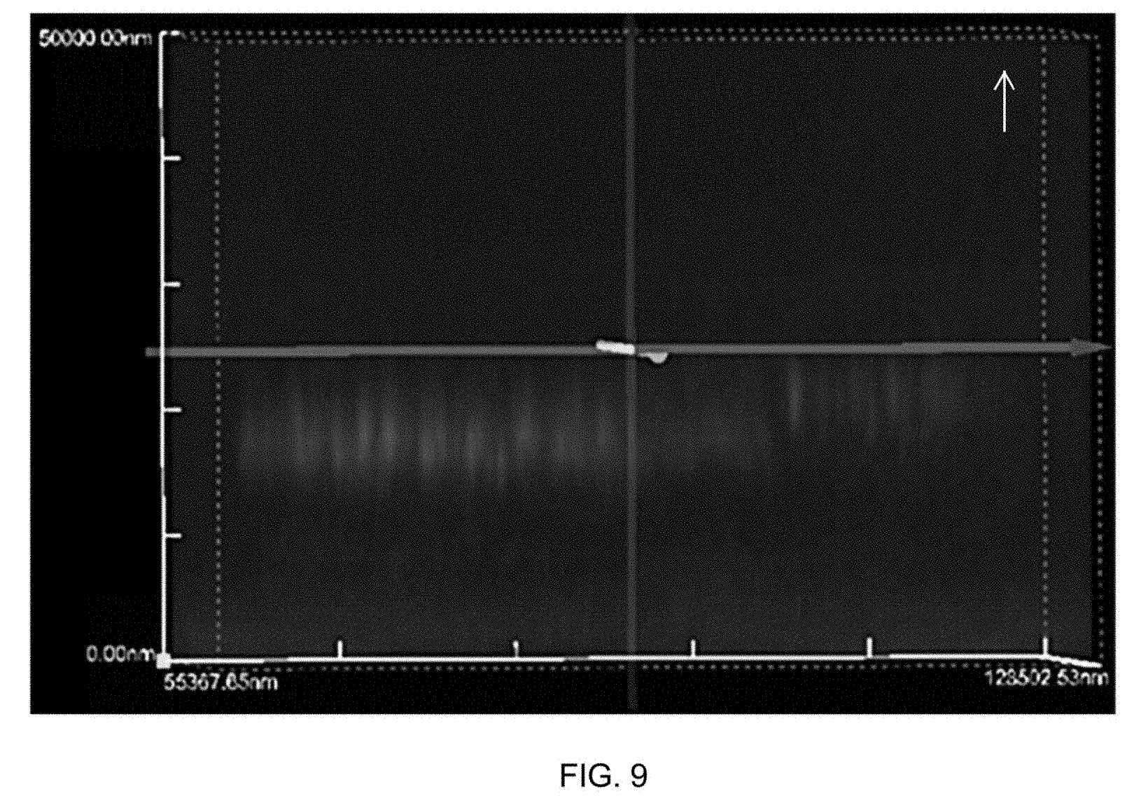

Referring to FIG. 9, nanosized, close-ended pores (“wells”) can be formed using the same process conditions described above corresponding with FIG. 8, using MGNCs without a magnetic field gradient. FIG. 9 shows a 3D confocal fluorescence image of wells formed in 50-μm PET film infiltrated with a fluorescent dye. The direction of well formation is indicated by an arrow pointed toward the top of the drawing. The wells stop at about Z=25 μm. This image evidences that a magnetic field gradient is not required to produce these pores, and further shows that blind pores (“wells”) can be formed, yet still be filled with materials by vacuum infiltration. As such, the pores may be formed with non-magnetic light-absorbing nanoparticles, such as gold nanoparticles, if desired.

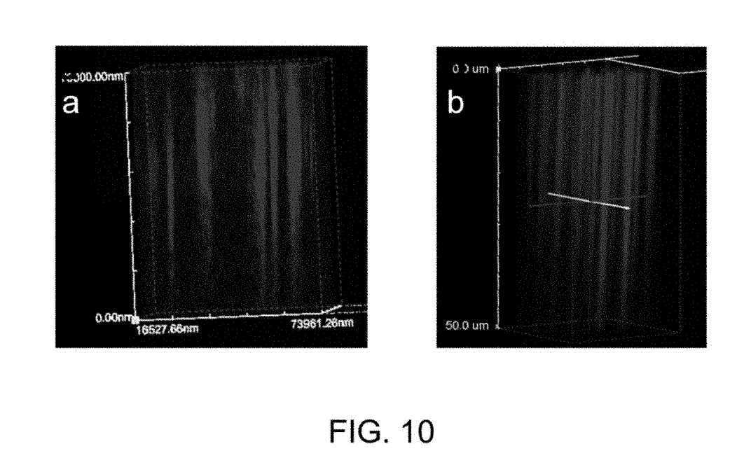

The above-noted process was also performed on other types of substrates. For example, FIG. 10 includes two 3D confocal fluorescence images of a substrate penetrated with MGNCs and subsequently infiltrated with rhodamine B. Image “a” is a 3-mil polydivinylfluoride (PVDF) substrate (75 μm thickness) and image “b” is a 2-mil polytetrafluoroethylene (PFTE) substrate (50 μm thickness). FIG. 2 includes SEM images demonstrating pores formed with MGNCs in non-porous borosilicate glass (Corning® Willow® glass) having a thickness of 100 μm.

PVDF has lower melting and glass transition temperatures (Tₘ and T_{g}) than PET and a higher coefficient of thermal expansion, resulting in pores with larger entrance apertures (about 0.4 to 1.7 μm) but tapered channels resulting in narrower exit apertures. PFTE and glass have much higher Tₘ and T_{g} values than PET, but nanosized open pores can still be generated with minimum substrate deformation. It should therefore be appreciated that PET, PVDF, PTFE, and glass membranes were used for demonstrative purposes, and such use is not intended to be limiting. Properties of these substrates are listed in Table 1.

TABLE 1
Substrates used in MGNC-based nanopore formation.

| | | Heat deflection | Tₘ [° C.] | CTE at 20° C. |
|---|---|---|---|---|
| | Thickness | temp. [° C.] at 264 | (ASTM | [ppm/° C.] |
| Substrate | [μm] | psi (ASTM D648) | D3418) | (ASTM D696) |
| PVDF | 75 | 110 | 166 | 130 |
| PET | 50 | 116 | 254 | 17 |
| (Melinex ® | | | | |
| 462; DuPont | | | | |
| Teijin) | | | | |
| PTFE | 50 | 55 | 335 | 135 |
| Borosilicate | 100 | 500 (upper limit | 700-750 | 4 |
| Willow ® | | on processing | (annealing | |
| glass | | temperature) | point) | |
| (Corning) | | | | |

It should be appreciated that the laser conditions used in these investigations could be modified to achieve high aspect-ratio wells or channels of desired dimensions for various substrates. For example, it has been observed that 50 to 150 pulses are sufficient to form complete channels through 50-μm PET membranes, whereas approximately 200 pulses was observed to produce a similar result in a glass substrate. The laser conditions and nanoparticles can also be tuned to controllably produce high aspect-ratio pores of different widths.

While the invention has been described in terms of specific or particular embodiments and investigations, it should be apparent that alternatives could be adopted by one skilled in the art. For example, the system for performing the processes and its components could differ in appearance and construction from the embodiments described herein and shown in the drawings, functions of certain components of the system could be performed by components of different construction but capable of a similar (though not necessarily equivalent) function, process parameters such as laser power, laser durations, number of laser pulses, and particle sizes could be modified, and appropriate materials could be substituted for those noted. In addition, the invention encompasses additional or alternative embodiments in which one or more features or aspects of different disclosed embodiments may be combined. Accordingly, it should be understood that the invention is not necessarily limited to any embodiment described herein or illustrated in the drawings. It should also be understood that the phraseology and terminology employed above are for the purpose of describing the disclosed embodiments and investigations, and do not necessarily serve as limitations to the scope of the invention. Therefore, the scope of the invention is to be limited only by the following claims.

1. A method comprising:
depositing a light-absorbing particle on a substrate; and
irradiating the particle with a pulsed laser beam to cause an increase in local temperature of a portion of the substrate contacted by and adjacent to the particle, enabling the particle to penetrate and migrate through the substrate to form a pore.

2. The method of claim 1, wherein the pore is produced in a direction normal to the surface of the substrate.

3. The method of claim 1, wherein the particle is one of a plurality of particles located on the substrate and the method comprises selectively irradiating at least some of the plurality particles with the pulsed laser beam to produce an array or pattern of pores in the substrate.

4. The method of claim 3, wherein the substrate is a web of thin film and the method comprises continuously depositing the plurality of particles on the substrate and continuously irradiating at least some of the plurality particles with the pulsed laser beam to produce the array or pattern of pores along the length of the web.

5. The method of claim 1, wherein the particle is a nanoparticle having an average diameter of 100 nm.

6. The method of claim 1, wherein the substrate has a thickness of 250 μm or less.

7. The method of claim 1, wherein the substrate comprises a thermoplastic, glass, or ceramic material.

8. The method of claim 1, wherein the particle comprises a magnetizable material and the method further comprises applying a magnetic field gradient to the particle as the particle is irradiated with the pulsed laser beam, wherein the magnetic field gradient promotes the movement of the particle within the substrate or directs the movement of the particle within the substrate.

9. The method of claim 8, further comprising aligning the pulsed laser beam and the magnetic field gradient along a common axis causing the particle to move through the substrate in a linear path along the common axis.

10. The method of claim 8, further comprising offsetting the alignment of the pulsed laser beam and the magnetic field gradient such that they are not aligned along a common axis causing the particle to move through the substrate in a nonlinear path.

11. The method of claim 8, further comprising generating the pore along a predetermined path by controlling the forces acting on the particle by the pulsed laser beam and the magnetic field gradient.

12. The method of claim 8, wherein the particle contains magnetizable material and an exterior coating thereon formed of non-magnetizable material.

13. The method of claim 1, further comprising filling the pore with a material that provides a functional capability independent of the properties of the substrate.

14. The method of claim 13, wherein the material provides sensing or actuating functions.

15. The method of claim 13, wherein the material provides means for detecting volatile analytes.

16. The method of claim 13, wherein the step of filling the pore produces a thin-film circuit.

17. The method of claim 13, wherein the particle comprises a magnetizable material and the method further comprises applying a magnetic field gradient to the particle that promotes the movement of the particle within the substrate or directs the movement of the particle within the substrate.

18. A product comprising a substrate having an array of open pores therein, the product formed by a method comprising the steps of:
locating a plurality of particles on the substrate; and
selectively irradiating at least some of the plurality of particles with a pulsed laser beam to cause an increase in a local temperature of portions of the substrate contacted by and adjacent to the particles, the particles penetrating and migrating through the substrate to form the array of open pores in the substrate.

19. The product of claim 18, wherein each of the plurality of particles comprises a magnetizable material and the method comprises applying a magnetic field gradient to the particles irradiated with the pulsed laser beam, wherein the magnetic field gradient promotes the movement of the particles within the substrate or directs the movement of the particles within the substrate.

20. The product of claim 18, wherein at least some of the open pores are filled with a material that provides a functional capability independent of the properties of the substrate.
